(19) United States
(12) Patent Application Publication
(10) Pub. No.: US 2013/0093489 A1
(43) Pub. Date: Apr. 18, 2013

(54) SIGNAL CONVERTER EQUIPPED WITH OVERVOLTAGE PROTECTION MECHANISM

(71) Applicants: Chun-Wei Lin, Douliu City (TW); Bing-Shiun Hsieh, Douliu City (TW)

(72) Inventors: Chun-Wei Lin, Douliu City (TW); Bing-Shiun Hsieh, Douliu City (TW)

(21) Appl. No.: 13/274,727

(22) Filed: Oct. 17, 2011

(51) Int. Cl. H03L 5/00

(52) U.S. Cl. 327/306

(57) ABSTRACT

A signal converter equipped with an overvoltage protection mechanism includes a pulse width modulation unit, a timing processing unit, an overvoltage detection unit, a pulse width control unit and a multi-level conversion unit. The pulse width modulation unit converts an analog signal into a pulse signal. The timing processing unit converts the pulse signal into a digital signal and outputs the digital signal to the overvoltage detection unit. When the digital signal is higher than the maximum limitation or less than the minimum limitation, the overvoltage detection unit outputs an over-threshold signal to the pulse width control unit to allow the pulse width modulation unit to perform feedback adjustment and prevent the multilevel conversion unit connected to the timing processing unit from causing burnout of downstream circuits because the multilevel conversion unit outputs maximum power intensity of signal over a long time.

### FIELD OF THE INVENTION

The present invention relates to a signal converter and particularly to a signal converter equipped with an overvoltage protection mechanism.

### BACKGROUND OF THE INVENTION

The current trend is towards fabricating slim, compact and portable multimedia products. In consideration of portable characteristic, the batteries of multimedia products should have longer running time to benefit portability. Besides, high fidelity and high sampling frequency should also be taken into account to effectively promote the audio quality of multimedia products.

Please refer to FIG. 1 for a block diagram of a conventional class D audio amplifier. The class D audio amplifier has very high power efficiency comparing to the linear amplifier—100% in theory. Because of high power efficiency, the class D audio amplifier generates less heat, and is free of additional heat sink. Therefore, the class D audio amplifier can be economically manufactured. The class D audio amplifier comprises a modulation circuit 1, an amplifier circuit 2 and a low-pass filter 3. The modulation circuit 1 usually uses a PWM (Pulse Width Modulation) function or a SDM (Sigma Delta Modulation) function. The modulation circuit 1 converts an input audio signal 5 into a two-level voltage signal 6 which is represented as pulse width. The two-level voltage signal 6 is used to control ON/OFF of the amplifier circuit 2 to perform current amplification. Then, the signal is restored through the low-pass filter 3 and outputted by a speaker 4. The input audio signal 5 is converted by the modulation circuit 1 into the two-level voltage signal 6, and the two-level voltage signal 6 is amplified by the amplifier circuit 2. After the amplification, the signal is still a two-level voltage signal 6. The succeeding low-pass filter 3 filters out the high-frequency harmonic wave to decrease the affection of noise and electromagnetic interference. In the time domain, the low-pass filter 3 functions as an integrator, and gradually accumulates or releases the signal levels or signal energy to restore the modulated signal.

The two-level voltage signal 6 has great instantaneous voltage difference. Thus, the low-pass filter 3 is hard to accumulate signal energy rapidly, and the signals are likely to have phase difference. Therefore, the output voltage has signal distortion 7 and cannot be easily restored to the audio signal with high fidelity and low distortion. Compared with the input audio signal 5 having sine wave, the two-level voltage signal 6 has much signal distortion 7.

A U.S. Pub. No. 20110019837 entitled “Multi-Level Output Signal Converter” discloses a multi-level signal converter converting a two-level voltage signal with high-level difference into a multi-level voltage signal with low-level difference, whereby is greatly simplified the design complexity of a conventional low-pass filter, and whereby is obviously decreased the high-frequency harmonic interference, and whereby is reduced the signal distortion caused by the amplifier circuit, and whereby is effectively increased the signal resolution. However, the greater the input signal, the higher the voltage of the output signal after being converted. If the output signal has a voltage higher than the threshold value, not only causes serious distortion but also damages the succeeding circuit.

To avert the damage of the downstream circuits, output voltage or current should be no higher than the threshold value of the downstream circuits. To meet this end a hard-clipping or soft-clipping approach is employed to reduce the output voltage or current when either is greater than the threshold value. But such an approach causes severe distortion.

### SUMMARY OF THE INVENTION

The primary object of the present invention is to improve the conventional hard-clipping or soft-clipping and provide desired adjustment of output voltage or current and prevent damage of downstream circuits caused by excessive high voltage or current that might result in severe element or system damage.

To achieve the foregoing object the invention provides a signal converter equipped with an overvoltage protection mechanism. It includes a pulse width modulation (PWM in short hereinafter) unit, a timing processing unit connected to the PWM unit, an overvoltage detection unit connected to the timing processing unit, a pulse width control unit and a multi-level conversion unit connected to the timing processing unit. The PWM unit converts an analog signal into a pulse signal. The width of the pulse signal is varied with the value of the analog signal. The timing processing unit receives the pulse signal and converts the pulse signal into a digital signal. The overvoltage detection unit receives the digital signal and outputs an over-threshold signal when it judges that the digital signal is a maximum threshold signal or a minimum threshold signal. The pulse width control unit is respectively connected to the overvoltage detection unit and PWM unit, and outputs a control signal to the PWM unit through the judgment of the overvoltage detection unit. The multi-level conversion unit receives the digital signal and converts the digital signal into a multi-level digital signal to output.

By means of the aforesaid technique of the invention, the overvoltage detection unit captures the digital signal of the timing processing unit, and the connection of the pulse width control unit and PWM unit forms a feedback to adjust the output voltage, thus preventing the downstream circuits from burnout because the multilevel conversion unit outputs maximum power intensity of signal over a long time.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a circuit block diagram of a convention technique.

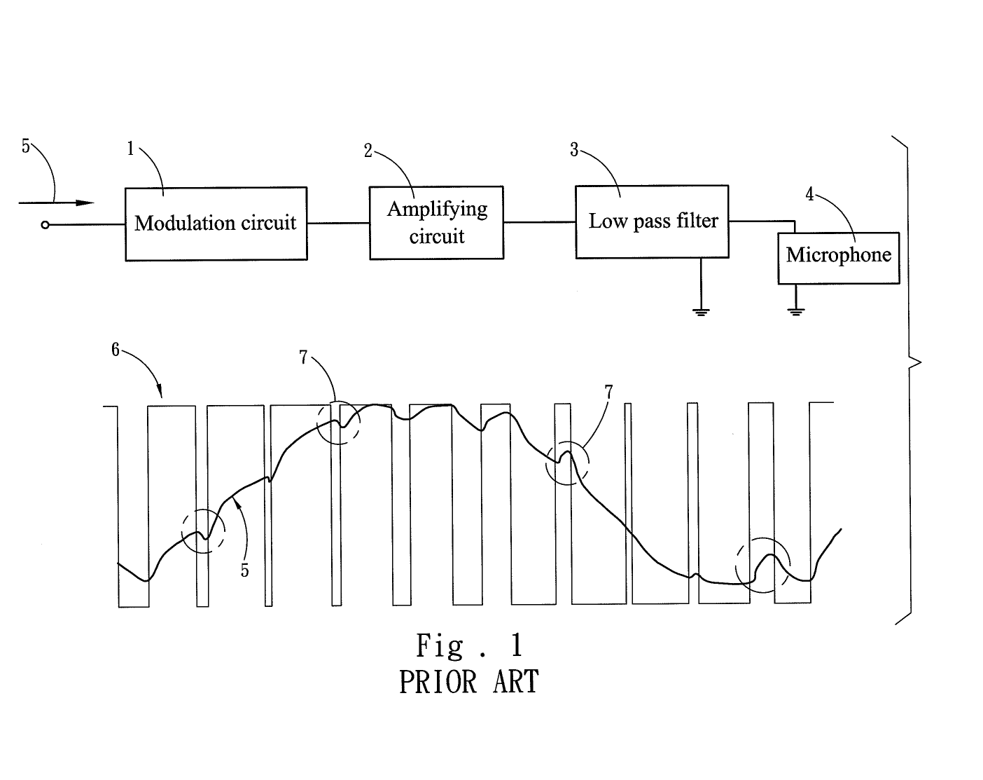

FIG. 2 is a schematic configuration of an embodiment of the invention.

FIG. 3 is a schematic circuit diagram of an embodiment of the overvoltage detection unit of the invention.

FIG. 4 is a schematic view of an embodiment of the pulse width control mechanism of the invention.

FIG. 5A is a block diagram of an embodiment of the PWM unit of the invention.

FIG. 5B is a schematic view of pulse width and converted waveform according to an embodiment of the invention.

FIG. 6 is a schematic view of clipping weight percentage according to an embodiment of the invention.

FIG. 7 is a schematic view of overload zones according to an embodiment of the invention.

FIG. 8 is a schematic view of heat generation rate according to an embodiment of the invention.

### DETAILED DESCRIPTION OF THE PREFERRED EMBODIMENTS

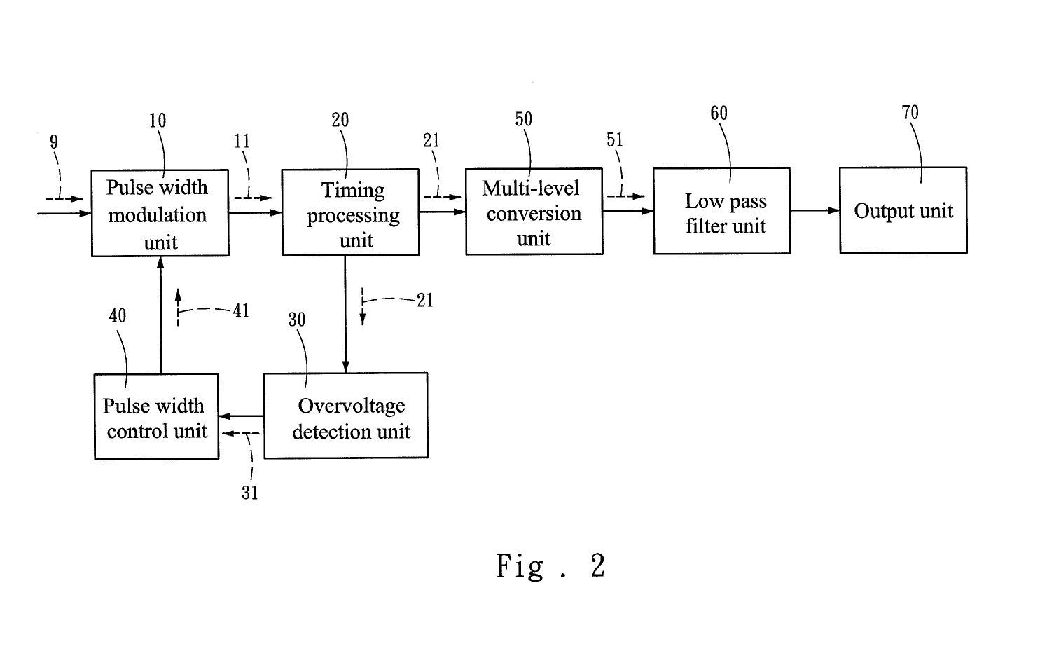

Please referring to FIG. 2, the present invention aims to provide a signal converter equipped with an overvoltage protection mechanism. It includes a PWM unit 10, a timing processing unit 20 connected to the PWM unit 10, an overvoltage detection unit 30 connected to the timing processing unit 20, a pulse width control unit 40 and a multi-level conversion unit 50 connected to the timing processing unit 20. The PWM unit 10 converts an analog signal 9 into a pulse signal 11. In this embodiment, the analog signal 9 is an audio output signal. The pulse signal 11 has a pulse width varied with the value of the analog signal 9. The timing processing unit 20 receives the pulse signal 11 and converts the pulse signal 11 into a digital signal 21. Different digital code combinations of the digital signals 21 respectively represent different pulse signals 11 and correspond to different values of the analog signals 9. For instance, a digital code of four bits can be chosen, and therefore the analog signal 9 can have values of 16 levels.

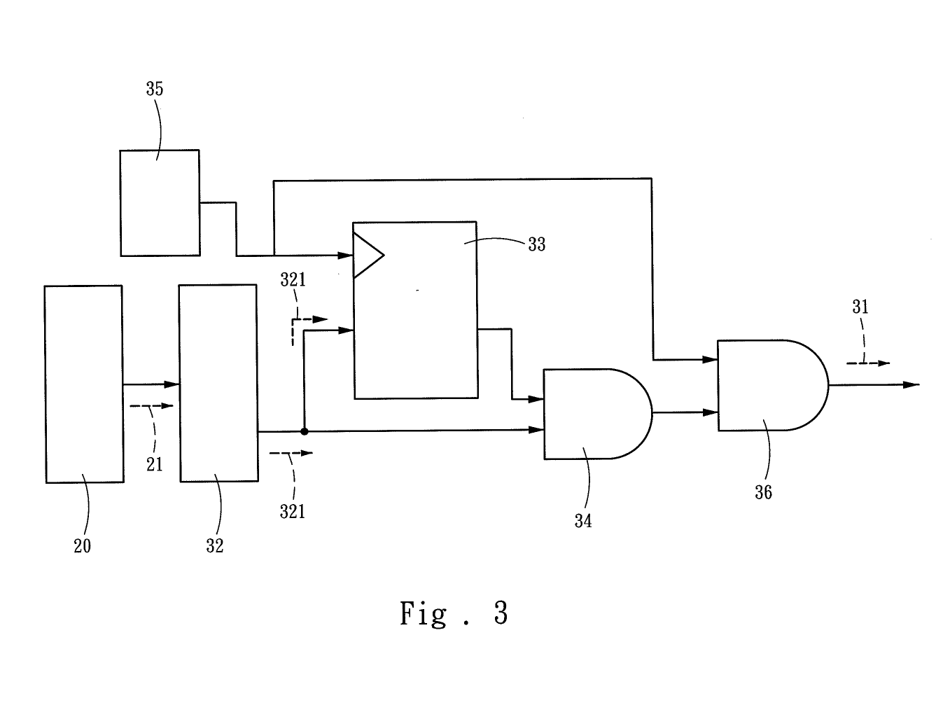

The overvoltage detection unit 30 receives the digital signal 21 and outputs an over-threshold signal 31 when it judges that the digital signal 21 is a maximum threshold signal or a minimum threshold signal. The digital code of the digital signal 21 corresponds to the value of the analog signal 9. When the analog signal 9 is greater than the maximum value bearable by the circuit, the digital signal 21 is indicated merely by a specific edited digital code, such as 1100 or 1111, i.e. the maximum threshold signal mentioned above. On the other hand, when the analog signal 9 is smaller than the bearable minimum value, the digital signal 2 is indicated merely by another specific edited digital code, such as 0000 or 0001, i.e. the minimum threshold signal mentioned above, in such an occasion the minimum value is a negative voltage. Hence when the negative value rises the circuit could also be damaged. Therefore, the overvoltage detection unit 30, by detecting whether the digital signal 21 is the maximum threshold signal or minimum threshold signal, judges whether the analog signal 9 has reached the maximum (or minimum) power output limit. Also referring to FIG. 3, the overvoltage detection unit 30 includes a decoder 32 connected to the timing processing unit 20, a timing delayer 33 connected to the decoder 32, and a first timing AND gate 34 respectively connected to the decoder 32 and timing delayer 33. The decoder 32 receives the digital signal 21 and outputs a judgment signal 321. More specifically, when the decoder 32 judges that the digital signal 21 is the maximum threshold signal or minimum threshold signal, it outputs 1 as the judgment signal 321, otherwise, outputs 0. The judgment signal 321 is respectively deferred by the timing delayer 33 to output to the first timing AND gate 34 and directly output to the first timing AND gate 34. If the two judgment signals 321 with front or rear timings are the same as 1, the analog signal 9 is judged greater than the maximum value or smaller than the minimum value, then whether to activate the pulse width control unit 40 to perform modulation is determined. Another alternative is to provide a clock generator 35 and a second timing AND gate 36 connected to the first timing AND gate 34 and clock generator 35 to perform count judgment, thereby to check time duration of the judgment signal 321 that maintains 1; after judging that the digital signal 21 has maintained at the maximum threshold signal or minimum threshold signal for a selected duration, the pulse width control unit 40 is activated to perform modulation.

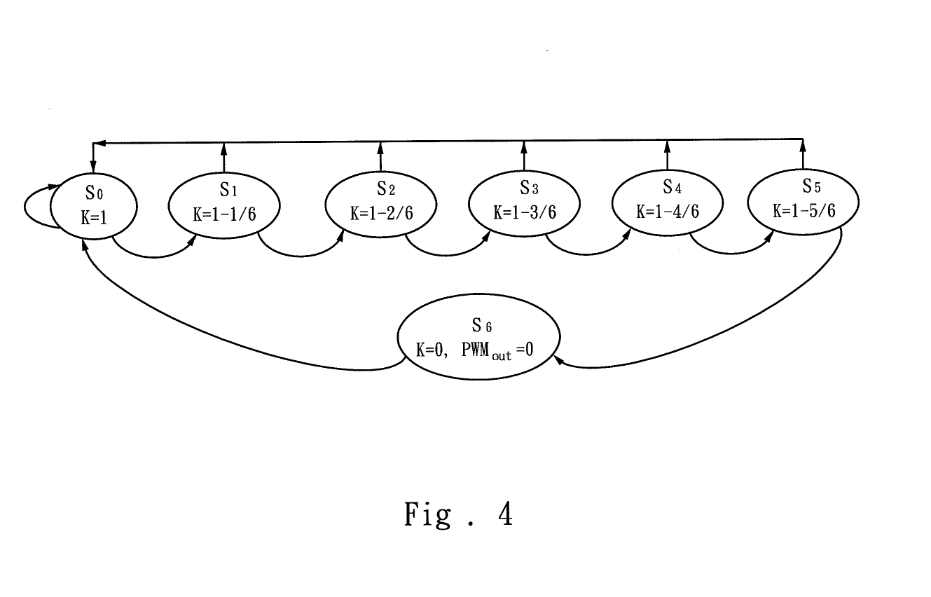

The pulse width control unit 40 is respectively connected to the overvoltage detection unit 30 and PWM unit 10, and outputs a control signal 41 to the PWM unit 10 through the judgment of the overvoltage detection unit 30. For instance, when the pulse width control unit 40 receives the over-threshold signal 31 the protection mechanism is activated. Also referring to FIG. 4, the protection mechanism is to control the value of an adjustment factor K which controls the pulse width output from the PWM unit 10. Details will be discussed later. The adjustment factor K is preset to be 1, which represents output is performed fully according to the input signal without any modulation. Upon the over-threshold signal 31 being received, the pulse width control unit 40 will reduce the adjustment factor K by a specific value firstly, such as six levels reducing as shown in the drawing, hence the specific value being ⅙. In the event that the over-threshold signal 31 is still received by the pulse width control unit 40 in future detection, the adjustment factor K is further reduced by ⅙ until no over-threshold signal 31 is received. It is to be noted that if the adjustment factor K has been reduced to 0, the circuit is judged in a short circuit condition or malfunctioned.

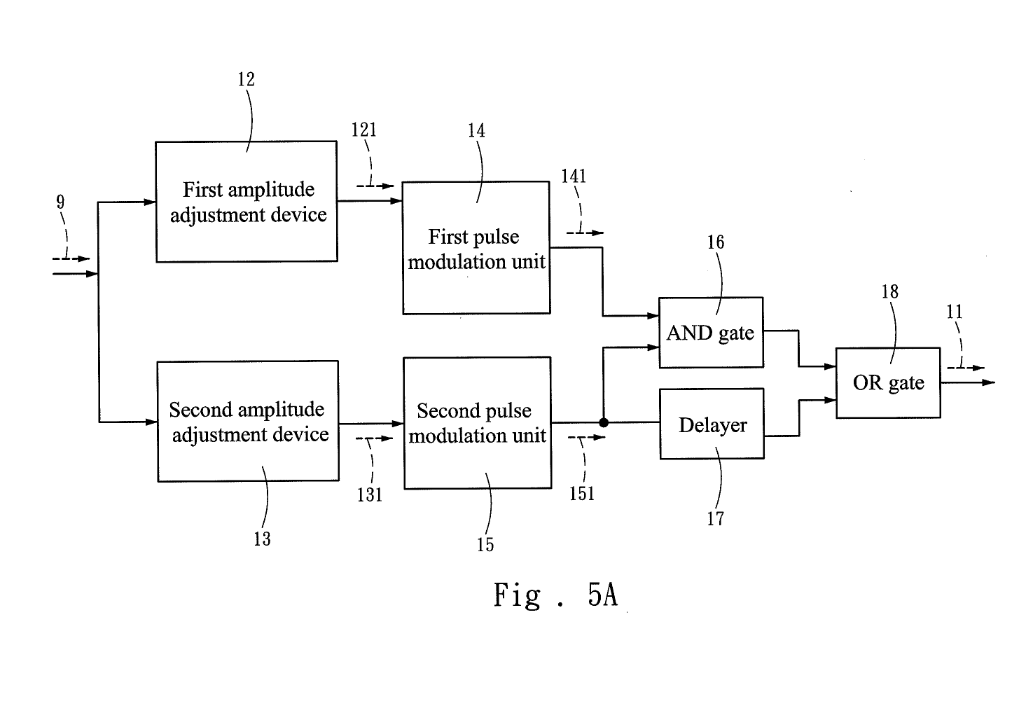

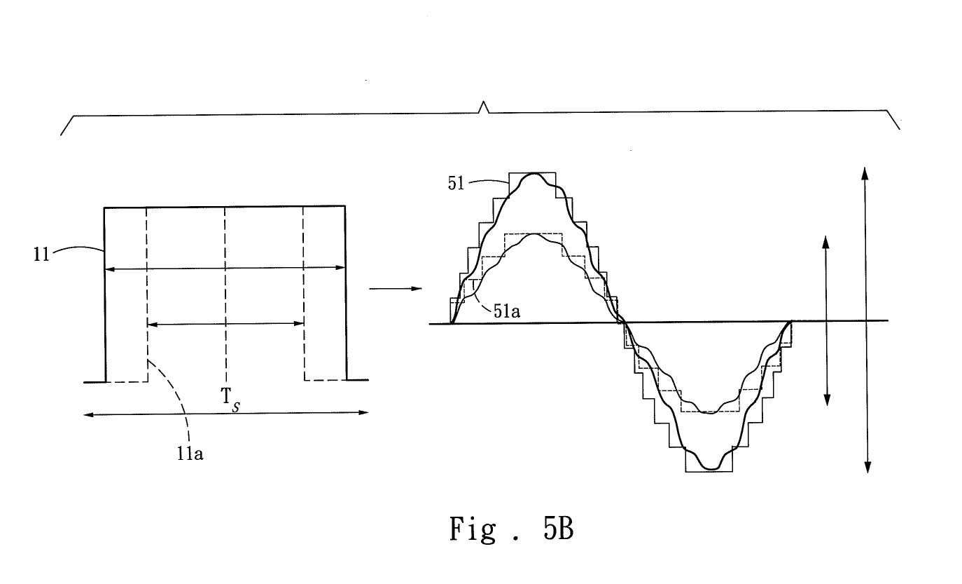

Referring to FIG. 5A, the PWM unit 10 includes a first amplitude adjustment device 12 and a second amplitude adjustment device 13 to receive the analog signal 9, a first pulse modulation unit 14 connected to the first amplitude adjustment device 12, a second pulse modulation unit 15 connected to the second amplitude adjustment device 13, an AND gate 16, a delayer 17 connected to the second pulse modulation unit 15 and an OR gate 18 respectively connected to the AND gate 16 and delayer 17. The first amplitude adjustment device 12 receives the analog signal 9 and converts the analog signal 9 into a first amplitude signal 121 to output. In this embodiment the first amplitude adjustment device 12 is a signal amplifier with an amplifying ratio being equal to the adjustment factor K previously discussed. The analog signal 9 multiplied by the adjustment factor K is the first amplitude signal 121. By setting 1 for the adjustment factor K of the first amplitude adjustment device 12, the analog signal 9 is directly sent backwards without enlarging or shrinking the amplitude. The first pulse modulation unit 14 is connected to the first amplitude adjustment device 12 to convert the first amplitude signal 121 into a first pulse modulation signal 141.

The second amplitude adjustment device 13 further is connected to the pulse width control unit 40 and has its adjustment factor K controlled thereby. The second amplitude adjustment device 13 adjusts the amplitude of the analog signal 9 through the adjustment factor K controlled by the controlled signal 41 and outputs a second amplitude signal 131, with the adjustment factor K smaller than or equal to 1. The adjustment method is like the one previously discussed. The second pulse modulation unit 15 is connected to the second amplitude adjustment device 13 to convert the second amplitude signal 131 into a second pulse modulation signal 151. The AND gate 16 is respectively connected to the first pulse modulation unit 14 and second pulse modulation unit 15 to receive the first pulse modulation signal 141 and second pulse modulation signal 151, thereby to perform logic gate processing. Also referring to FIG. 5B, to incorporate with the processing of the AND gate 16 the width of the front half cycle of the pulse signal 11 is controlled, i.e. the amplitude of the positive half cycle of the multi-level digital signal 51 is controlled. By connecting the delayer 17 and ON gate 18, the width of the rear half cycle of the pulse signal 11 is controlled, i.e. the amplitude of the negative half cycle of the multi-level digital signal 51 is controlled. Thus, by modulating the second pulse modulation signal 151 the original pulse signal 11 is converted into a modulated pulse signal 11a. The pulse signal 11 also is processed by the timing processing unit 20 and sent to the multi-level conversion unit 50 so that the digital signal is converted into a multi-level digital signal 51 to be output. After the pulse signal 11 is modulated, the original multi-level digital signal 51 also is converted with the modulated pulse signal 11a to become a modulated multi-level digital signal 51a to prevent the voltage from exceeding the threshold value to cause severe distortion or damage of the downstream circuits.

Referring to FIG. 2, the invention further includes a low pass filter unit 60 connected to the multi-level conversion unit 50 to receive the multi-level digital signal 51 and an output unit 70 connected to the low pass filter unit 60 for outputting. The invention employs the overvoltage detection unit 30 to generate a feedback protection mechanism to protect the output unit 70. Take an audio circuit as an example, the output unit 70 can be a loudspeaker, a megaphone, and a headphone or the like.

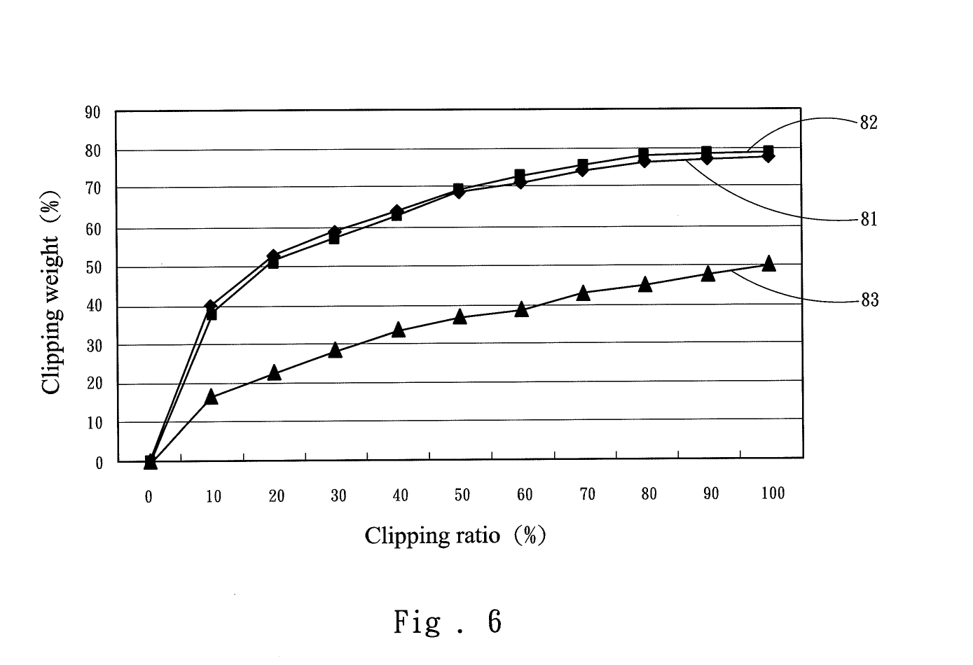

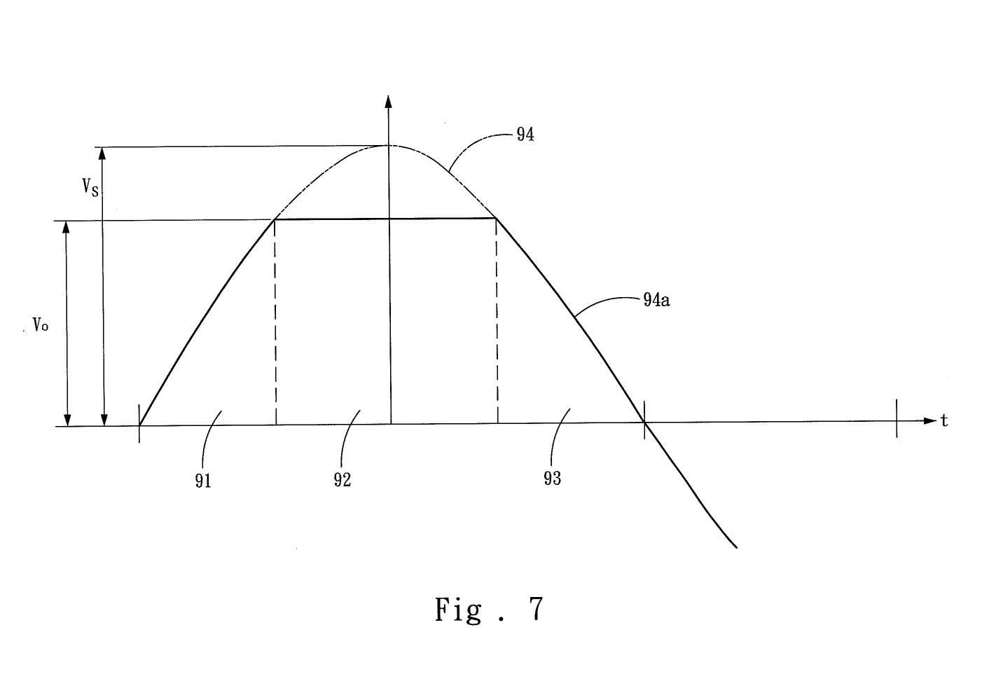

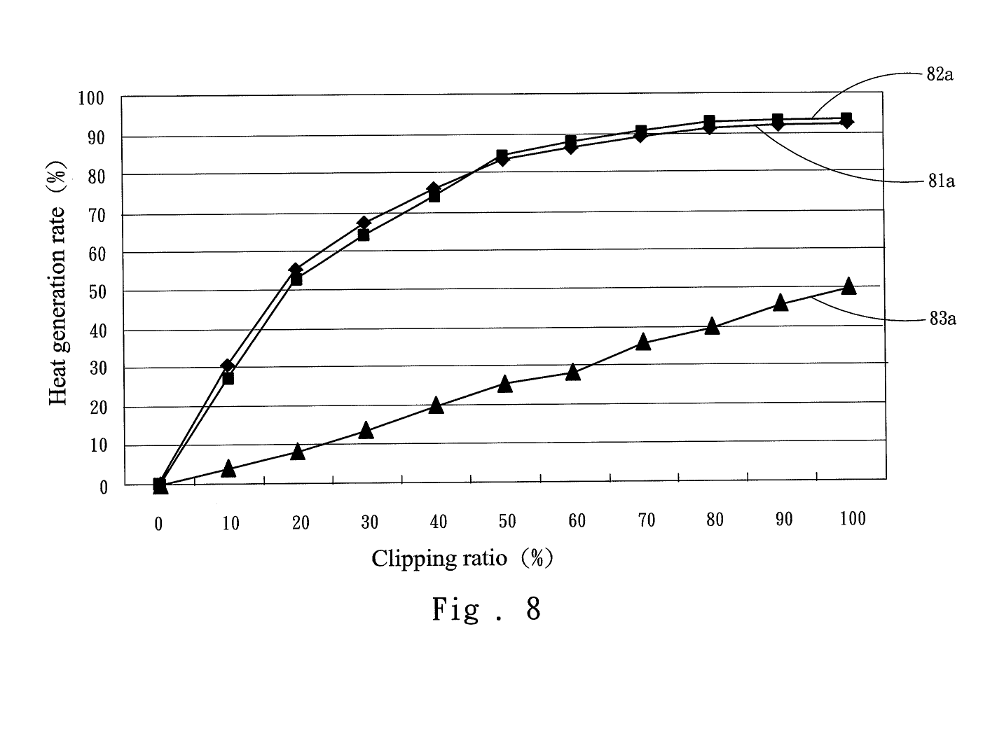

Referring to FIG. 6, the clipping ratio represents the difference, between the intended output voltage and a set threshold voltage of the circuit, divided by the threshold voltage. Hence a greater clipping ratio means that the difference of the intended output voltage and threshold voltage is greater. Also referring to FIG. 7, the output waveform 94 exceeding a threshold value Vo is set for a second zone 92, while other output waveform 94a not exceeding the threshold value Vo is set for a first zone 91 or a third zone 93, the clipping weight represents the weight ratio of the intended output voltage exceeding the threshold voltage over the total output including the integration of each voltage in a time interval, i.e. the ratio of the second zone 92 over the total amount (first zone 91+second zone 92+third zone 93). A smaller ratio is more desirable. Referring to FIG. 6, compared with a hard-clipping curve 81 resulting from hard-clipping and a soft-clipping curve 82 resulting from soft-clipping to avoid voltage overload, the circuit provided by the invention bears a protection mechanism curve 83 with much improved clipping weight than the hard-clipping curve 81 and soft-clipping curve 82. This proves that the invention can reduce the weight ratio of actual output voltage exceeding the threshold voltage. The square of the weight ratio is proportional to heat generation rate. Also referring to FIG. 8, heat generated according to the protection mechanism curve 83a via the circuit of the invention is much less than that of the hard-clipping curve 81a and soft-clipping curve 82a. Thus it can be deducted that the structure provided by the invention can reduce thermal loss resulting from transformation of the intended output voltage exceeding the threshold voltage, i.e. by reducing power loss to reduce heat generation of total circuits.

As a conclusion, the invention captures the digital signal 21 of the timing processing unit 20 through the overvoltage detection unit 30, and forms a feedback via connection of the pulse width control unit 40 and PWM unit 10 to modulate output voltage to avoid output of excessive high voltage signals and burnout of the downstream circuits. It provides a significant improvement over the conventional techniques.

While the preferred embodiments of the invention have been set forth for the purpose of disclosure, modifications of the disclosed embodiments of the invention as well as other embodiments thereof may occur to those skilled in the art. Accordingly, the appended claims are intended to cover all embodiments which do not depart from the spirit and scope of the invention.

What is claimed is:

1. A signal converter equipped with an overvoltage protection mechanism, comprising:
a pulse width modulation unit converting an analog signal into a pulse signal whose width varies with a value of the analog signal;
a timing processing unit connected to the pulse width modulation unit to receive the pulse signal and convert the pulse signal into a digital signal;
an overvoltage detection unit connected to the timing processing unit to receive the digital signal and output an over-threshold signal upon judging that the digital signal is a maximum threshold signal or a minimum threshold signal;
a pulse width control unit respectively connected to the overvoltage detection unit and the pulse width modulation unit to output a control signal to the pulse width modulation unit according to the judgment of the overvoltage detection unit; and
a multi-level conversion unit connected to the timing processing unit to receive the digital signal and convert the digital signal into a multi-level digital signal to output.

2. The signal converter of claim 1, wherein the overvoltage detection unit includes:
a decoder connected to the timing processing unit to receive the digital signal and output a judgment signal;
a timing delayer connected to the decoder to receive the judgment signal and delay output; and
a first timing AND gate connected to the decoder and the timing delayer to respectively receive the judgment signal and another judgment signal having been delayed.

3. The signal converter of claim 2, wherein the decoder outputs 1 as the judgment signal after judging that the digital signal is the maximum threshold signal or the minimum threshold signal, otherwise outputs 0.

4. The signal converter of claim 3, wherein the overvoltage detection unit further includes a clock generator and a second timing AND gate respectively connected to the first timing AND gate and the clock generator, by which the time duration of the judgment signal being maintained at 1 can be checked.

5. The signal converter of claim 1, wherein the pulse width modulation unit includes:
a first amplitude adjustment device to receive the analog signal and convert the analog signal into a first amplitude signal;
a second amplitude adjustment device to receive the analog signal and connect to the pulse width control unit, wherein the second amplitude adjustment device adjusts the amplitude of the analog signal through an adjustment factor controlled by the control signal and outputs a second amplitude signal, wherein the second amplitude signal equals to the analog signal multiplied by the adjustment factor, and the adjustment factor is smaller than or equal to 1;
a first pulse modulation unit connected to the first amplitude adjustment device to convert the first amplitude signal into a first pulse width modulation signal;
a second pulse modulation unit connected to the second amplitude adjustment device to convert the second amplitude signal into a second pulse width modulation signal;
an AND gate respectively connected to the first pulse modulation unit and the second pulse modulation unit;
a delayer connected to the second pulse modulation unit to defer the second pulse width modulation signal; and
an OR gate respectively connected to the AND gate and the delayer.

6. The signal converter of claim 5, wherein the first amplitude adjustment device directly outputs the analog signal when the adjustment factor equal to 1, and the first and second amplitude adjustment devices are signal amplifiers.

7. The signal converter of claim 1 further including a low pass filter unit connected to the multi-level conversion unit to receive the multi-level digital signal and including an output unit connected to the low pass filter unit.

8. The signal converter of claim 7, wherein the output unit is selected from the group consisting of a loudspeaker, a megaphone, and a headphone.
